(19) United States
(12) Patent Application Publication
(10) Pub. No.: US 2026/0268993 A1
(43) Pub. Date: Sep. 10, 2026

(54) MULTI-PORT MEMORY TESTING USING CONCURRENT OPERATIONS

(71) Applicant: Siemens Industry Software Inc., Plano, TX (US)

(72) Inventors: Benoit Nadeau-Dostie, Gatineau (CA); Wei Zou, Wilsonville, OR (US); Albert Au, Ottawa (CA)

(73) Assignee: Siemens Industry Software Inc., Plano, TX (US)

(21) Appl. No.: 19/165,616

(22) PCT Filed: Mar. 24, 2023
(86) PCT No.: PCT/US2023/016206

§ 371 Date: Sep. 16, 2025

(51) Int. Cl. G11C 29/10

(52) U.S. Cl. CPC G11C 29/10

(57) ABSTRACT

A memory-testing circuit in a circuit configured to perform a test on one or more memories in the circuit, of which each has a plurality of logical ports. The memory-testing circuit comprises: a test algorithm control unit configured to implement a test algorithm, a reference address generator configured to generate, based on the test algorithm, a reference address, one or more concurrent address generators configured to generate, based on the reference address, one or more concurrent addresses, and address selecting circuitry for each of the one or more memories configured to select, based on an address selection signal, the reference address or one of the one or more concurrent addresses for each of the plurality of logical ports. One logical port is configured to receive an algorithm command and the reference address, while the other logical ports are configured to receive concurrent commands and the concurrent addresses.

### FIELD OF THE DISCLOSED TECHNIQUES

The presently disclosed techniques relate to embedded memory test. Various implementations of the disclosed techniques may be particularly useful for testing multi-port memory.

### BACKGROUND OF THE DISCLOSED TECHNIQUES

Multi-port memory has multiple independent access ports. Each access port can be coupled to one processor or a part of one processor through a bus that includes address, data, and control lines. These independent access ports along with the associated buses allow multiple processors to simultaneously read from or write to different areas of the memory, without interfering with each other. Such parallel operations can reduce the bottleneck of memory access, leading to faster data transfer and processing. Multi-port memory can also be used to implement shared memory systems in a networking environment. In a packet-switched network, for example, a shared memory system can be used to store packets that are being transmitted between nodes. Through different access ports, these nodes can access the memory at the same time without interfering with each other. This can lead to high throughput, low latency, and simplified system design.

Designed tightly to the technology limits, memories are more prone to failures than other circuits, which can affect not only manufacture yield but also circuit reliability adversely. Built-in self-test (BIST) techniques are typically employed to identify defects and problems in the memories for both manufacturing test and in-system test. Conventional memory test solutions have difficulties in testing multi-port memories in a setting similar to practical applications. One challenge is how to test all bit line coupling and word line coupling faults in a reasonable amount of time even if the memory layout is not known. Another challenge is how to enable simultaneous access to all ports while avoiding conflicts. Still another challenge is how to avoid attempting read or write operations outside of the memory address range. A solution that can overcome one or more of these challenges, minimize the amount of additional test circuitry, and avoid modifications to the memories under test is thus highly desirable.

### BRIEF SUMMARY OF THE DISCLOSED TECHNIQUES

Various aspects of the disclosed technology relate to multi-port memory testing. In one aspect, there is a memory-testing circuit in a circuit configured to perform a test on one or more memories in the circuit, each of the one or more memories having a plurality of logical ports, the plurality of logical ports being divided into a plurality of test ports, each of the plurality of test ports being capable of both write and read operations and comprising one or two logical ports, the memory-testing circuit comprising: a test algorithm control unit configured to implement a test algorithm, the test algorithm comprising a sequence of read and write operations, each execution of the test algorithm performing a memory test through one of the plurality of test ports, one logical port in the test port under test configured to receive an algorithm command corresponding to one read operation or one write operation in the sequence of read and write operations, logical ports that are not receiving the algorithm command configured to receive concurrent commands generated based on the test algorithm; a reference address generator configured to generate, based on the test algorithm, a reference address for the one logical port in the test port under test; one or more concurrent address generators configured to generate, based on the reference address, one or more concurrent addresses for the logical ports that receive the concurrent commands; a test port counter configured to increment after each execution of the test algorithm and generate a test port count signal; and address selecting circuitry for each of the one or more memories configured to select, based on an address selection signal, the reference address or one of the one or more concurrent addresses for each of the plurality of logical ports, the address selection signal being generated based on the test port count signal.

The memory-testing circuit may further comprise: a global control signal generator configured to generate, based on the test algorithm, the algorithm command and the concurrent commands; and a local control signal generator in a memory test interface circuit for each of the one or more memories, the local control signal generator configured both to deliver the algorithm command to the one logical port in the test port under test and the concurrent commands to the logical ports that are not receiving the algorithm command and to generate, based on the test port count signal, the address selection signal.

The address selection signal may comprise a row address selection signal and a column address selection signal and may be configurable to allow a logical port to receive row address of the one of the one or more concurrent addresses and column address of the reference address, column address of the one of the one or more concurrent addresses and row address of the reference address, or both the row address and the column address of the one of the one or more concurrent addresses.

The one or more concurrent address generators may comprise: a global concurrent address generator configured to generate a global concurrent address based on the reference address; and a local concurrent address generator in a memory test interface circuit for each of the one or more memories, the local concurrent address generator configured to receive the global concurrent address and to output the one or more concurrent addresses. The one or more concurrent addresses may be the same as the global concurrent address. Alternatively, the local concurrent address generator is configured to generate the one or more concurrent addresses based on the global concurrent address, no more than one of the one or more concurrent addresses for write-capable logical ports being the same as the global concurrent address.

Row address of the global concurrent address may be derived from row address of the reference address by adding or subtracting 1, and column address of the global concurrent address may be derived from column address of the reference column address by adding or subtracting 1. The adding or subtracting 1 may be based on whether the reference address changes in an ascending order or in a descending order.

Each of the one or more concurrent addresses may be obtained at least in part by applying a concurrent address mask to one or more bits of the reference address. The concurrent address mask may replace selected bits of the reference address with a unique fixed bit pattern, inverts one or a unique combination of selected bits of the reference address, or both.

Each of the one or more concurrent address generators may be in a memory test interface circuit coupled to each of the one or more memories. Each of the one or more concurrent address generators may comprise: inverter circuitry configured to invert a least significant bit of an intermediate concurrent address, the intermediate concurrent address being the reference address or the reference address minus an offset; and bit replacing circuitry to replace selected bits of the intermediate concurrent address with different fixed bit patterns for different logical ports. The inverting and the replacing may be performed on both row address and column address, and wherein the address selection signal may comprise a row address selection signal and a column address selection signal and may be configurable to allow a logical port to receive row address of the one of the one or more concurrent addresses and column address of the reference address, column address of the one of the one or more concurrent addresses and row address of the reference address, or both the row address and the column address of the one of the one or more concurrent addresses.

Some or all of the one or more concurrent address generators may comprise address threshold checking circuitry configured to output row address of the intermediate concurrent address, the row address of the intermediate concurrent address being the same as row address of the reference address if the row address of the reference address is smaller than a predetermined threshold value or an address obtained by subtracting an value from the row address of the reference address if the row address of the reference address is greater than or equal to the predetermined threshold value.

In another aspect, there is one or more computer-readable media storing computer-executable instructions for causing a computer to perform a method, the method comprising: creating, in a circuit design, the above memory-testing circuit.

Certain inventive aspects are set out in the accompanying independent and dependent claims. Features from the dependent claims may be combined with features of the independent claims and with features of other dependent claims as appropriate and not merely as explicitly set out in the claims.

Certain objects and advantages of various inventive aspects have been described herein above. Of course, it is to be understood that not necessarily all such objects or advantages may be achieved in accordance with any particular embodiment of the disclosed techniques. Thus, for example, those skilled in the art will recognize that the disclosed techniques may be embodied or carried out in a manner that achieves or optimizes one advantage or group of advantages as taught herein without necessarily achieving other objects or advantages as may be taught or suggested herein.

### BRIEF DESCRIPTION OF THE DRAWINGS

FIG. 1 illustrates an example of a block diagram of a typical memory.

FIG. 2 illustrates an example block diagram of a memory-testing circuit that may be implemented according to various embodiments of the disclosed technology.

FIG. 3 illustrates four examples of test ports.

FIG. 4 illustrates an example block diagram of a memory-testing circuit for testing multi-port memories that may be implemented according to various embodiments of the disclosed technology.

FIG. 5 illustrates an example block diagram of a memory-testing circuit for testing one or more multi-port memories based on using the same concurrent address for inactive logical ports that may be implemented according to various embodiments of the disclosed technology.

FIG. 6 illustrates an example block diagram of a memory-testing circuit for testing one or more multi-port memories based on using a unique concurrent address for each of inactive logical ports that may be implemented according to various embodiments of the disclosed technology.

FIG. 7 illustrates an example block diagram of a memory test interface circuit for testing a multi-port memory based on using different concurrent addresses for inactive logical ports that may be implemented according to various embodiments of the disclosed technology.

FIG. 8 illustrates an example block diagram of circuit for generating unique concurrent write data for an inactive write-capable logical port that may be implemented according to various embodiments of the disclosed technology.

FIG. 9 illustrates an example block diagram of parallel comparison circuitry for concurrent read data that may be implemented according to various embodiments of the disclosed technology.

FIG. 10 illustrates an example block diagram of serial comparison circuitry for concurrent read data that may be implemented according to various embodiments of the disclosed technology.

FIG. 11 illustrates a programmable computer system with which various embodiments of the disclosed technology may be employed.

### DETAILED DESCRIPTION OF THE DISCLOSED TECHNIQUES

Various aspects of the disclosed technology relate to multi-port memory testing. In the following description, numerous details are set forth for the purpose of explanation. However, one of ordinary skill in the art will realize that the disclosed technology may be practiced without the use of these specific details. In other instances, well-known features have not been described in details to avoid obscuring the disclosed technology.

Some of the techniques described herein can be implemented in software instructions stored on a computer-readable medium, software instructions executed on a computer, or some combination of both. Some of the disclosed techniques, for example, can be implemented as part of an electronic design automation (EDA) tool. Such methods can be executed on a single computer or on networked computers.

The detailed description of a method or a device sometimes uses terms like “generate” and “perform” to describe the disclosed method or the device function/structure. Such terms are high-level descriptions. The actual operations or functions/structures that correspond to these terms will vary depending on the particular implementation and are readily discernible by one of ordinary skill in the art.

As used in this disclosure, the singular forms “a,” “an,” and “the” include the plural forms unless the context clearly dictates otherwise. Additionally, the term “includes” means “comprises.” Moreover, unless the context dictates otherwise, the term “coupled” means electrically or electromagnetically connected or linked and includes both direct connections or direct links and indirect connections or indirect links through one or more intermediate elements not affecting the intended operation of the circuit.

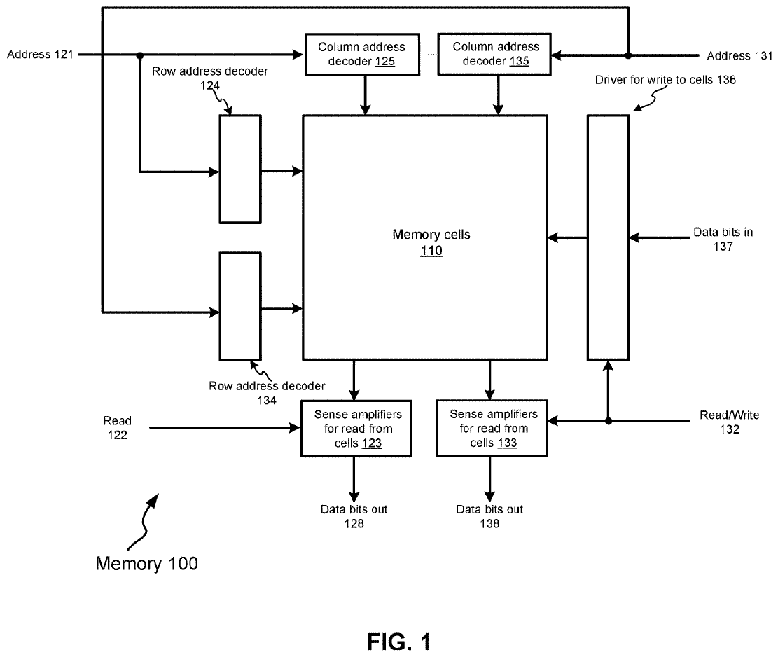

Memories form a large part of system-on-chip circuits. Embedded memories can provide higher bandwidth and consume lower power than stand-alone memories. FIG. 1 illustrates an example block diagram of a memory 100 having a read-only logical port and a read-write logical port. The memory 100 comprises memory cells 110, two column address decoders 125 and 135, two row address decoders 124 and 134, driver circuitry 136, and two sets of sense amplifiers 123 and 133. The column address decoder 125, the row address decoders 124, and the sense amplifiers 123 are coupled to corresponding inputs of the read-only logical port, an address input 121 and a control input 122. The sense amplifiers 123 are also coupled to a data output 128 of the read-only logical port. The column address decoder 135, the row address decoders 134, the sense amplifiers 133, and the driver circuitry 136 are coupled to corresponding inputs of the read-write logical port, an address input 131, a control input 122, and a data input 137. The sense amplifiers 133 are also coupled to a data output 138 of the read-write logical port.

The memory cells 110 are connected in a two-dimensional array. Each of the memory cells 110 can store one bit of binary information. The memory cells 110 can be grouped into memory words of fixed word length, for example 1, 2, 4, 8, 16, 32, 64 or 128 bit. It should be noted that the word length is not limited to powers of 2. A memory cell has two fundamental components: storage node and select device. The storage node stores the data bit for the memory cell, and the select device component facilitates the memory cell to be addressed to read/write in an array.

The row address decoders 124, 134 and the column address decoders 125, 135 determine the cell addresses that need to be accessed according to logical addresses at the address inputs 121, 131, respectively. Based on the address signals outputted from the row address decoders 124, 134 and the column address decoders 125, 135, the corresponding row(s) and column(s) get selected and connected to the sense amplifiers 123, 133 during read operation. Each of the sense amplifiers 123, 133 amplifies and sends out a data bit. For written operation, the required cells where the data bits need to be written are selected the address signals outputted from the row address decoder 134 and the column address decoder 135, and the driver circuitry 136 is used to write data bits into the selected memory cells.

Memories can have a significant impact on yield as they occupy a large area of the system-on-chip design and have a small feature size. However, memory cells typically do not include logic gates and flip-flops. Memory faults thus behave differently than classical stuck-at faults for logic circuits. The large size and high density of memory cell arrays are also not suitable for using external test patterns. As a result, MBIST (memory built-in self-test)-based techniques have become widely adopted for both manufacture testing and in-system testing. MBIST may implement a finite state machine (FSM) to generate and apply stimuli to memories. The responses coming out of memories can then be analyzed to detect faults. MBIST-based techniques can add repair circuitry to the memory-testing circuit. The repair circuitry can analyze testing results and redundancy information and allocate spare rows and/or columns of storage cells to faulty rows and/or columns. The repair can reduce yield loss and extend lifespan of manufactured chips.

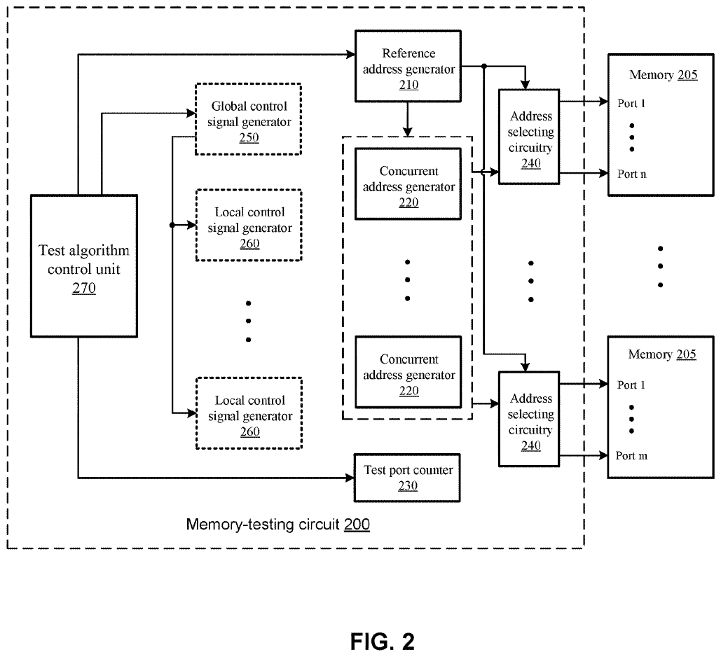

FIG. 2 illustrates an example block diagram of a memory-testing circuit 200 that may be implemented according to various embodiments of the disclosed technology. The memory-testing circuit 200 is configured to perform a test on one or more memories 205. Each of the one or more memories 205 has a plurality of logical ports. The number of logical ports for one memory in the one or more memories 205 can be the same as or different from the number of logical ports for another memory in the one or more memories 205. In addition to testing the one or more multi-port memories 205, the memory-testing circuit 200 can also be configured to test one or more single-port memories simultaneously.

A logical port can be a write-only port, a read-only port, or a read-write port. A write-only port can perform a write operation according to a control signal for the write operation, data bits to be stored in the memory, and an address signal indicating in which memory cells the data bits to be stored. A write-only port also includes a data input port for receiving the data bits to be stored in the memory cells. A read-only port can perform a read operation according to a control signal for the read operation and an address signal indicating from which memory cells data bits to be read. A read-only port also includes a data output port for outputting the data bits read from the memory cells. A read-write port can perform either a write operation or a read operation depending on a control signal received. A read-write port also includes a data input port for write operation, a data output port for read operation, and an address port for both write and read operations.

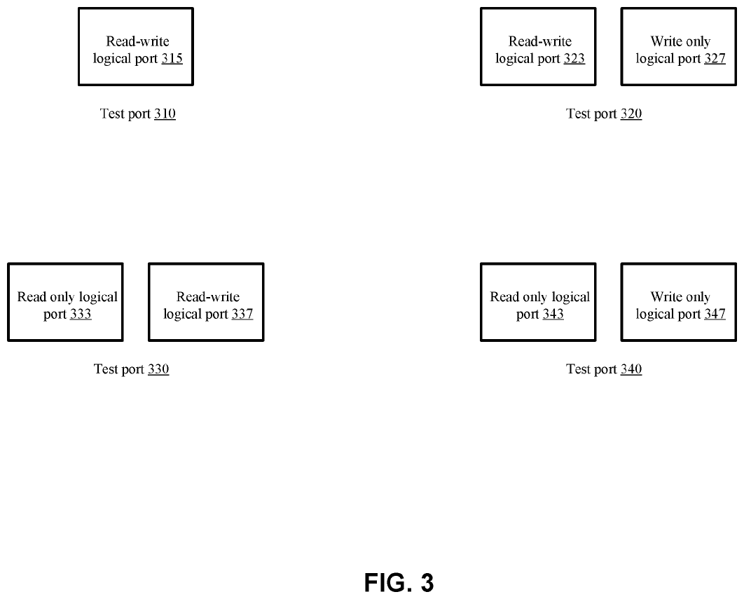

For testing purposes, logical ports can be divided into test ports by memory test interface circuitry coupled to each of the multi-port memories 205. For testing purposes, a test port needs to have both read and write capabilities. Thus, a test port typically can have one or two logical ports. FIG. 3 illustrates fours examples of test ports 310-340. The test port 310 is formed by a read-write logical port 315. The test port 320 is formed by a read-write logical port 323 and a write-only logical port 327. The test port 330 is formed by a read-only logical port 333 and a read-write logical port 337. The test port 340 is formed by a read-only logical port 343 and a write-only logical port 347. In the second example, the test port 320 uses only the read capability of the read-write logical port 323, and the read-write logical port 323 itself is configured to be another test port for memory test. In the third example, the test port 330 uses only the write capability of the read-write logical port 333, and the read-write logical port 333 itself is configured to be another test port for memory test.

Referring back to FIG. 2, the memory-testing circuit 200 comprises a test algorithm control unit 270, a reference address generator 210, one or more concurrent address generators 220, a test port counter 230, and address selecting circuitry 240 for each of the one or more memories 205. The test algorithm control unit 270 is configured to implement a test algorithm. The test algorithm comprises a sequence of read and write operations. Various test algorithms can be employed. One example memory test algorithm is March C− algorithm, which includes the following operations: write 0s (to initialize); read 0s, write 1s in an address ascending order (from address 0 to address n−1); read 1s, write 0s in the address ascending order; read 0s, write 1s in an address descending order (from address n−1 to address 0); read 1s, write 0s in the address descending order, and reads 0s. Another memory test algorithm, Checkerboard algorithm, includes the following operations: write checkerboard in the address ascending order; read checkerboard in the address ascending order; write inverse checkerboard in the address ascending order; and read inverse checkerboard in the address ascending order.

Each execution of the test algorithm implemented by the test algorithm control unit 270 can performed a memory test through one of the plurality of test ports (referred to as test port under test) for each of the one or more memories 205. One logical port in the test port under test is configured to receive an algorithm command corresponding to one read operation or one write operation in the sequence of read and write operations, and logical ports that are not receiving the algorithm command can be configured to receive concurrent commands generated based on the test algorithm. The logical port that receives an algorithm command may be referred to as an active logical port while the logical ports that receive the concurrent commends may be referred to as inactive logical ports. Both the algorithm commands and the concurrent commands can cause read or write operations on the memory through the active logical port and the inactive logical ports, respectively. If a test port under test has two logical ports, each of the two logical ports can be an active logical port for one operation of the test algorithm and an inactive logical port for another operation of the test algorithm.

The test algorithm control unit 270 can comprise a finite state machine and is typically placed in an MBIST controller. The reference address generator 210 is configured to generate, based on the test algorithm, a reference address for the active logical port in the test port. This reference address can be an address for read operation or an address for write operation depending on the current operation of the test algorithm. The reference address generator 210 can be placed in the MBIST controller as well.

The one or more concurrent address generators 220 are configured to generate, based on the reference address, one or more concurrent addresses for the inactive logical ports. The one or more concurrent address generators 220 can be placed solely in the MBIST controller, solely in a memory test interface circuit for each of the one or more memories 205, or some of them in the MBIST controller and the rest in the memory test interface circuit for each of the one or more memories 205. For example, the one or more concurrent address generators 220 may comprise a global concurrent address generator which is placed in the MBIST controller and a local concurrent address generator for each of the one or more memories 205 which is placed in the memory test interface circuit for that memory. In this setup, the global concurrent address generator can be configured to generate a global concurrent address based on the reference address; and the local concurrent address generators can be configured to receive the global concurrent address and output the one or more concurrent addresses. The concurrent addresses can be the same for all or some of the inactive logical ports. The concurrent addresses can also be unique for each of the inactive logical ports.

The test port counter 230 is configured to increment after each execution of the test algorithm and generate a test port count signal. It can be placed in the MBIST controller. The test port count signal can be used to generate an address selection signal which can be used by the address selecting circuitry 240.

The address selecting circuitry 240 is placed in the memory test interface circuit for each of the one or more memories 205. The address selecting circuitry 240 is configured to select, based on the address selection signal, the reference address or one of the one or more concurrent addresses for each of the plurality of logical ports. The address selection signal may comprise a row address selection signal and a column address selection signal, which can be configured independently. This can allow a logical port to receive row address of a concurrent address and column address of the reference address, column address of a concurrent address and row address of the reference address, or both the row address and the column address of a concurrent address.

The memory-testing circuit 200 may further comprise a global control signal generator 250 and a local control signal generator 260 for each of the one or more memories 205. The global control signal generator 250 can be placed in the MBIST controller while the local control signal generator 260 can be placed in the memory test interfaces for the one or more memories 205. The global control signal generator 250 can be configured to generate, based on the test algorithm, the algorithm command and the concurrent commands. The local control signal generators can be configured to deliver the algorithm command to the active logical port in the test port under test and the concurrent commands to the inactive logical ports. The local control signal generators can also be configured to generate, based on the test port count signal, the address selection signal for the address selecting circuitry 240.

The memory-testing circuit 200 can also comprise a test data generator which is not shown in the figure. The test data generator is typically placed in the MBIST controller and is configured to provide the data to be written into or the data to be read from the one or more memories 205 based on the test algorithm. The data to be read from the one or more memories 205 can be used to compare the data outputted from the one or more memories 205 in a read operation for determining whether the memory under test has a defect or not.

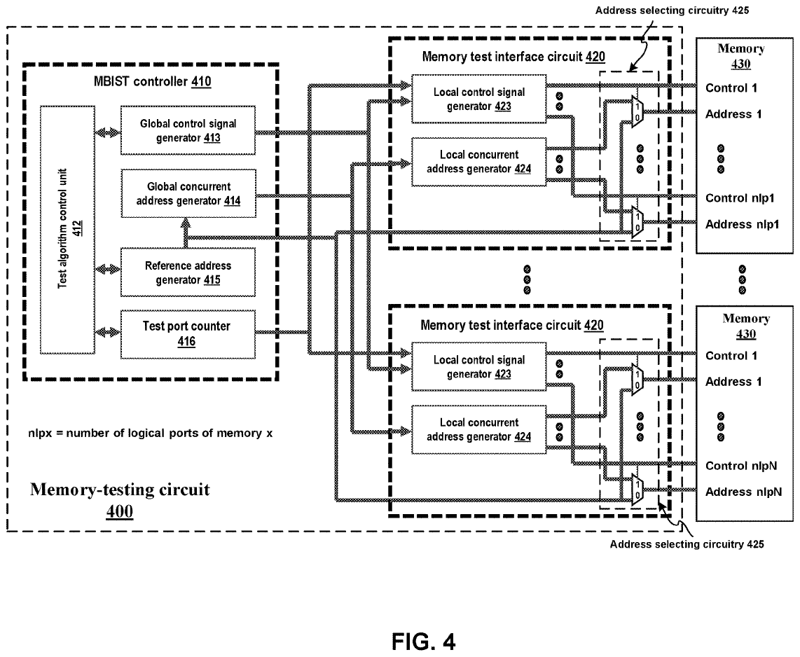

FIG. 4 illustrates an example block diagram of a memory-testing circuit 400 for testing multi-port memories 430 that may be implemented according to various embodiments of the disclosed technology. The memory-testing circuit 400 comprises an MBIST controller 410 and memory test interface circuits 420. The MBIST controller 410 comprises a test algorithm control unit 412, a global control signal generator 413, a global concurrent address generator 414, a reference address generator 415, and a test port counter 416. The memory-testing circuit 400 can also comprise a test data generator configured to provide the data to be written into or the data to be read from the multi-port memories 430. Each of the memory test interface circuits 420 comprises a local control signal generator 423, a local concurrent address generator 424, and address selecting circuitry 425. Each of the memory test interface circuits 420 is coupled to one of the multi-port memories 430.

The test algorithm control unit 412 can be configured to implement a test algorithm for testing the multi-port memories 430. The global control signal generator 413 can be configured to generate, based on the test algorithm, algorithm commands for active logical ports and concurrent commands for inactive logical ports, and send them to the local control signal generators 423. An active logical port for each of multi-port memories 430 is a logical port in a test port under test that receives an algorithm command corresponding to a memory operation in the sequence of read and write operations defined by the test algorithm. The rest of the logical ports for each of multi-port memories 430 are referred to as inactive logical ports. Through the inactive logical ports, concurrent memory operations are performed based on concurrent commands. As described previously, when a test port has two logical ports, their roles as being active or inactive may be switched between memory operations.

The local control signal generators 423 can be configured to deliver the received algorithm command to the active logical port and the received concurrent commands to the inactive logical ports for each of the multi-port memories 430. The local control signal generators 423 can further be configured to generate, based on a test port count signal, the address selection signal for the address selecting circuitry 425. The test port count signal can be generated by the test port counter 416 which can be configured to increment after each execution of the test algorithm.

The reference address generator 415 can be configured to generate, based on the test algorithm, a reference address for the active logical port for each of the multi-port memories 430. The global concurrent address generator 414 can be configured to generate a global concurrent address based on the reference address. The local concurrent address generator 423 can be configured to receive the global concurrent address and output the one or more concurrent addresses. One or all of the concurrent addresses may be set to be the same as the global concurrent address. The concurrent addresses may be set in such a way that each inactive port receives a unique concurrent address.

The address selecting circuitry 425 can be configured to select, based on the address selection signal provided by the local control signal generators 423, the reference address or one of the one or more concurrent addresses for each of the plurality of logical ports for each of the multi-port memories 430. In this example, the address selecting circuitry 425 employs a plurality of 2-to-1 multiplexers to perform the selecting operation. The two inputs for each of the 2-to-1 multiplexers are coupled to the reference address and one of the one or more concurrent addresses, respectively, and the select input is coupled to the address selection signal from the local control signal generators 423.

As discussed with respect to the memory-testing circuit 200 in FIG. 2, the address selection signal may comprise a row address selection signal and a column address selection signal, which can be configured independently. This will allow a logical port to receive row address of a concurrent address and column address of the reference address, column address of a concurrent address and row address of the reference address, or both the row address and the column address of a concurrent address. Accordingly, two 2-to-1 multiplexers can be employed for selecting addresses for each of the plurality of logical ports.

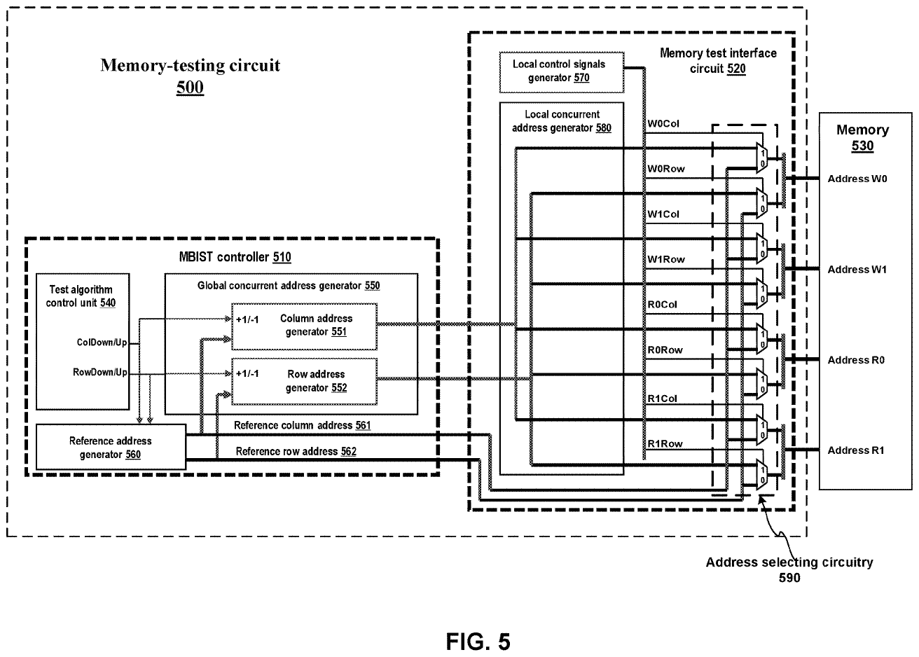

FIG. 5 illustrates an example block diagram of a memory-testing circuit 500 for testing one or more multi-port memories 530 based on using the same concurrent address for inactive logical ports that may be implemented according to various embodiments of the disclosed technology. The memory-testing circuit 500 comprises an MBIST controller 510 and a memory test interface circuit 520 for each of the one or more multi-port memories 530. While only one multi-port memory 530 is shown in the figure, the memory-testing circuit 500 can test multiple multi-port memories. In such a case, a memory test interface circuit like the memory test interface circuit 520 can be added for each of the additional multi-port memories.

The MBIST controller 510 comprises a test algorithm control unit 540, a global concurrent address generator 550, and a reference address generator 560. Similar to the MBIST controller 410 in FIG. 4, the MBIST controller 510 can further comprise a global control signal generator, a test port counter, and a test data generator. The test algorithm control unit 540 can be configured to implement a test algorithm. The reference address generator 560 can be configured to generate, based on the test algorithm, a reference address comprising a reference column address 561 (column address of the reference address) and a reference row address 562 (row address of the reference address). The global concurrent address generator 550 comprises a column address generator 551 and a row address generator 552. The column address generator 551 can be configured to add “1” to the reference column address 561 to generate a concurrent row address if the reference column address 561 is increasing based on the test algorithm or subtract “1” from the reference column address 561 if the reference column address 561 is decreasing based on the test algorithm. Similarly, the row address generator 552 can be configured to add “1” to the reference row address 562 to generate a row concurrent address if the reference row address 562 is increasing based on the test algorithm or subtract “1” from the reference row address 562 if the reference row address 562 is decreasing based on the test algorithm.

The memory test interface circuit 520 comprises a local control signal generator 570, a local concurrent address generator 580, and address selecting circuitry 590. The address selecting circuitry 590 comprises 2-to-1 multiplexers. Each logical port of the multi-port memory 530 receive address signals from outputs of two of the 2-to-1 multiplexers, one for row address and the other for column address. The local concurrent address generator 580 is configured to broadcast to the 2-to-1 multiplexers the concurrent column address or the concurrent row address, both received from the global concurrent address generator 550. Each of the 2-to-1 multiplexers also receives the reference column address 561 or the reference row address 562. The local control signal generator 570 is configured to provide address selection signals to the 2-to-1 multiplexers, one for selecting between the concurrent column address and the reference column address 561 and the other for selecting between the concurrent row address and the reference row address 562.

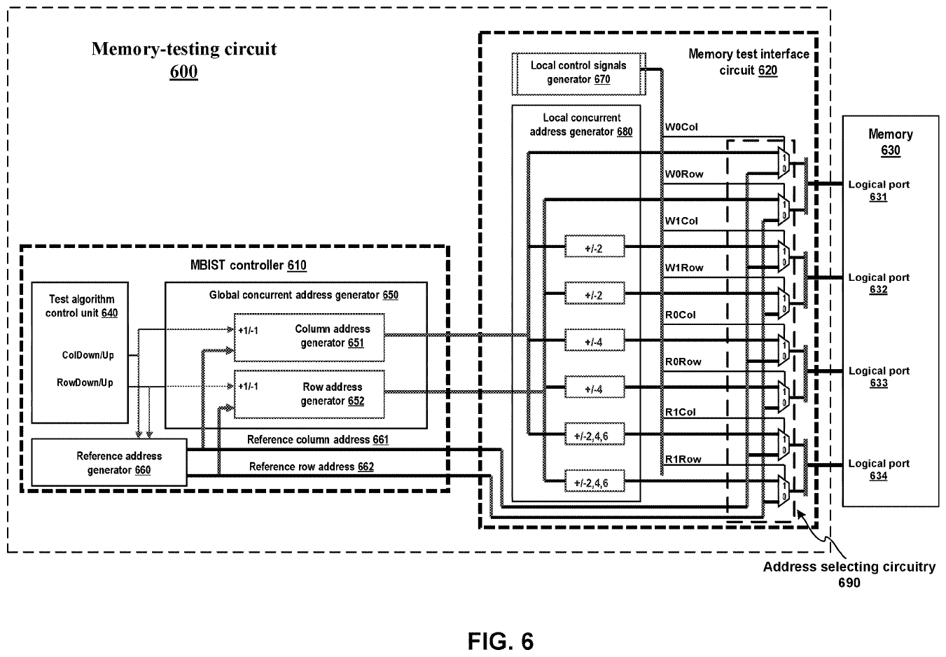

FIG. 6 illustrates an example block diagram of a memory-testing circuit 600 for testing one or more multi-port memories 630 based on using a unique concurrent address for each of inactive logical ports that may be implemented according to various embodiments of the disclosed technology. The memory-testing circuit 600 comprises an MBIST controller 610 and a memory test interface circuit 620 for each of the one or more multi-port memories 630. Again for simplicity, only a pair of one multi-port memory 630 and one memory test interface circuit 620 are shown in the figure.

The MBIST controller 610 comprises a test algorithm control unit 640, a global concurrent address generator 650, and a reference address generator 660. The test algorithm control unit 640 can be configured implement a test algorithm. The reference address generator 660 can be configured to generate, based on the test algorithm, a reference address comprising a reference column address 661 and a reference row address 662. The global concurrent address generator 650 comprises a column address generator 651 and a row address generator 652. Like the column address generator 551 in FIG. 5, the column address generator 651 can be configured to generate a global column concurrent address by either adding/subtracting “1” to/from the reference column address 661. Similarly, the row address generator 652 can be configured to generate a global concurrent row address by either adding/subtracting “1” to/from the reference row address 662.

The memory test interface circuit 620 comprises a local control signal generator 670, a local concurrent address generator 680, and address selecting circuitry 690. The address selecting circuitry 690 comprises 2-to-1 multiplexers. Each logical port of the multi-port memory 630 receive address signals from outputs of two of the 2-to-1 multiplexers, one for row address and the other for column address. Unlike the broadcasting function performed by the local concurrent address generator 580 in FIG. 5, the local concurrent address generator 680 can be configured to generate, based on the global concurrent column and row addresses, different concurrent column and row addresses for different logical ports. For a first logical port 631, the concurrent column and row addresses are the same as the global concurrent column and row addresses. For a second logical port 632, the concurrent column and row addresses are derived by inverting the second least significant bits of the global concurrent column and row addresses. For a third logical port 633, the concurrent column and row addresses are derived by inverting the third least significant bits of the global concurrent column and row addresses. For a fourth logical port 634, the concurrent column and row addresses are derived by inverting both the second least significant bits and the third least significant bits of the global concurrent column and row addresses.

The local control signal generator 670 is configured to provide the address selection signals to the 2-to-1 multiplexers, selecting a column address from between the reference column address and the concurrent column address provided by the local concurrent address generator 680 661 and selecting a row address from between the reference row address 662 and the concurrent row address provided by the local concurrent address generator 680.

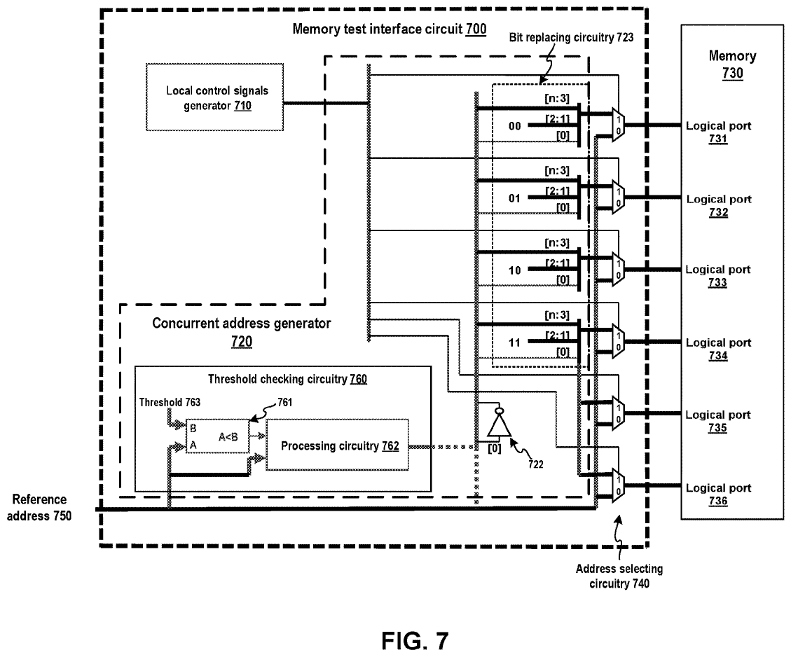

FIG. 7 illustrates an example block diagram of a memory test interface circuit 700 for testing a multi-port memory 730 that may be implemented according to various embodiments of the disclosed technology. The memory test interface circuit 700 comprises a local control signal generator 710, a concurrent address generator 720, and address selecting circuitry 740. The concurrent address generator 720 can be configured to generate different concurrent addresses for logical ports 731-736 based on a reference address 750. The reference address 750 can be generated by a reference address generator in an MBIST controller, as illustrated in the three examples shown in FIGS. 4-6. The address selecting circuitry 740 can be configured to select addresses for the logical ports 731-736 between the concurrent addresses and the reference address 750. The local control signal generator 710 can be configured to generate an address selection signal for the address selecting circuitry 740.

The concurrent address generator 720 comprises address threshold checking circuitry 760, inverter circuitry 722, and bit replacing circuitry 723. The threshold checking circuitry 760 comprises comparison circuitry 761 and processing circuitry 762. The comparison circuitry 761 can be configured to compare the reference address 750 with a predetermined threshold value. The processing circuitry 762 can be configured to generate an intermediate concurrent address from the reference address 750 based on the comparison result from the comparison circuitry 761. If the reference address 750 is smaller than the predetermined threshold value, the intermediate concurrent address will be the same as the reference address 750. If the reference address 750 is greater than or equal to the predetermined threshold value, the intermediate concurrent address will be an address obtained by subtracting an offset value from the reference address 750.

The address threshold checking circuitry 760 can prevent any concurrent address from exceeding the range of the multi-port memory 730. The address threshold checking circuitry 760 may be used only for concurrent row addresses when the number of rows for the memory 730 is not a power of 2. Concurrent column addresses cannot exceed the range because the number of columns is typically a power of 2.

The inverter circuitry 722 can be configured to invert the least significant bit of the intermediate concurrent address outputted from the address threshold checking circuitry 760. The bit replacing circuitry 723 can be configured to output concurrent addresses by replacing selected bits of the intermediate concurrent address with different fixed bit patterns for some of the logical ports. As shown in the figure, the two bits immediately after the least significant bit of the intermediate concurrent address, i.e., bits [2:1], are replaced with “00”, “01”, “10”, “11” for the logical ports 731-734, respectively. The bit replacing circuitry 723 essentially applies concurrent address masks to two bits of the intermediate concurrent address to generate four different concurrent addresses for the logical ports 731-734, respectively. The logical ports 735-736 share the same concurrent address with the logical gate 734. In one example, the logical ports 731-733 may be write-only logical ports while the logical ports 734-736 may be read-only logical ports.

Similar to the memory test interface circuit 500 in FIG. 5 and the memory test interface circuit 600 in FIG. 6, the address selection signal generated by the local control signal generator 710 can comprise a row address selection signal and a column address selection signal which can be configurable independently, enabling a logical port to receive row address of the concurrent address and column address of the reference address 750, column address of the concurrent address and row address of the reference address 750, or both the row address and the column address of the concurrent address. For simplicity, do not show FIG. 7 does not show separate circuits for concurrent row and column addresses in both the concurrent address generator 720 and the address selecting circuitry 740.

In contrast to the two examples shown in FIGS. 5 and 6, the concurrent addresses are generated solely by the concurrent address generator 720 in the memory test interface circuit 700 based on the reference address 750. In the example shown in FIG. 5, the local concurrent address generator 580 in the memory test interface circuit 520 only broadcast the same concurrent address to the inactive logical ports through the address selecting circuitry 590. It is the global concurrent address generator 550 in the MBIST controller 510 that generates the concurrent address based on the reference address. In the example shown in FIG. 6, both the global concurrent address generator 650 in the MBIST controller 610 and the local concurrent address generator 680 in the memory test interface circuit 620 operate in tandem to generate the concurrent addresses for the inactive logical ports. Employing fixed concurrent address masks and generating concurrent addresses locally the memory test interface circuits like the example shown in FIG. 7 may lead to small silicon area and simplicity for handling memories with incomplete address space.

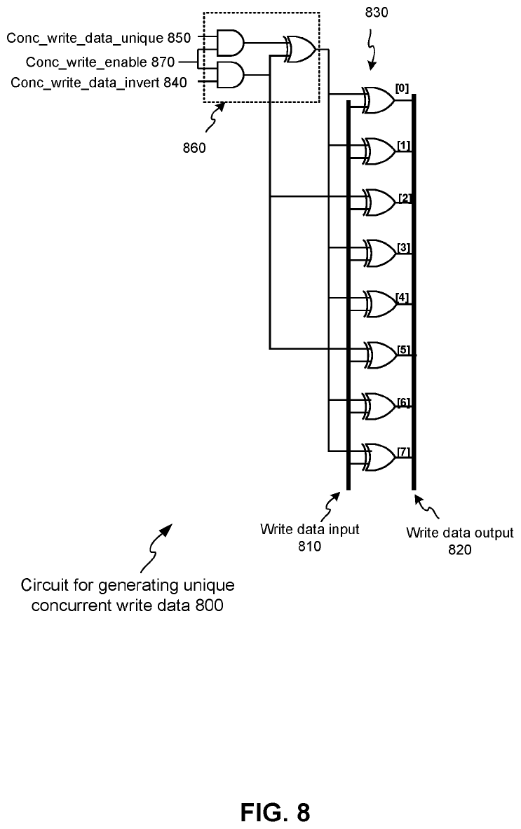

FIG. 8 illustrates an example block diagram of circuit 800 for generating unique concurrent write data for an inactive write-capable logical port (inactive write-only logical port or inactive read-write logical port) that may be implemented according to various embodiments of the disclosed technology. The circuit 800 for generating unique concurrent write data comprises a plurality of XOR gates 830 and a control circuit 860. The plurality of XOR gates 830 are configured to invert some preset bits of write data from a write data input 810 based on control signals from the control circuit 860 and output the result at a write data output 820. The number of the plurality of XOR gates 830 can be determined based on the number of inactive logical ports. The control circuit 860 is configured to generate the control signals based on a conc_write_data_unique control signal 850, a conc_write_enable control signal 870, and a conc_write_data_invert control signal 840. When the conc_write_enable control signal 870 is “0”, no bit of the input write data is inverted. When the three control signals are “1”, “1”, “0”, only bits [0]-[1], [3]-[4], [6]-[7] are inverted. When the three control signals are “1”, “1”, “1”, only bits [2] and [5] are inverted. When the three control signals are “0”, “1”, “1”, bits [0]-[7] are inverted. The control signals can be coupled to different combinations of XOR gates in the plurality of XOR gates 810 to generate different concurrent write data.

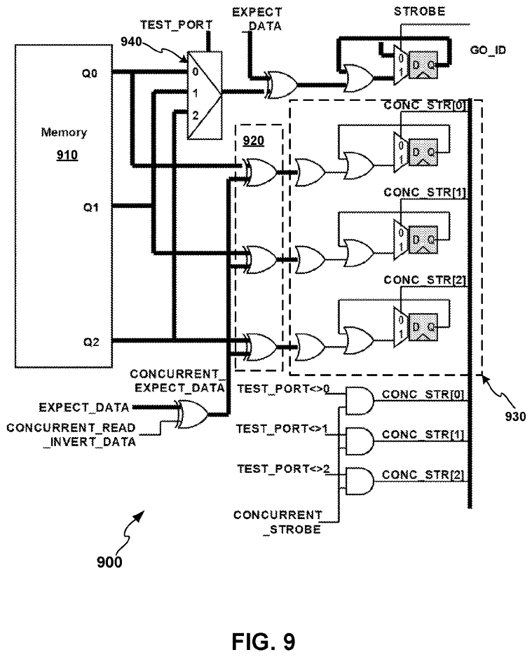

A memory-testing circuit may comprise a comparator comparing the output of a read-capable logical port (a read-only logical port or a read-write logical port) with the expected data value after performing a concurrent read command, and a result register detecting if at least one comparison failed during the execution of the test algorithm. FIG. 9 illustrates an example block diagram of parallel comparison circuitry 900 for concurrent read data that may be implemented according to various embodiments of the disclosed technology. The parallel comparison circuitry 900 comprises comparator circuitry 920, sticky status bit circuitry 930 and a multiplexer 940. A memory 910 has three read output ports Q0, Q1 and Q2, each being coupled to a comparator in the comparator circuitry 920 which is in turn coupled to a sticky status bit in the sticky status bit circuitry 930. As such, the comparison can be performed simultaneously for all of the three read-capable logical ports. During execution of a test algorithm, one of the read output ports Q0, Q1 and Q2 is part of the test port (active read output port) while the other two output concurrent read data. The output of the active read output port is also selected by the multiplexer 940 for comparing with expected data. The concurrent read addresses could be the same or different.

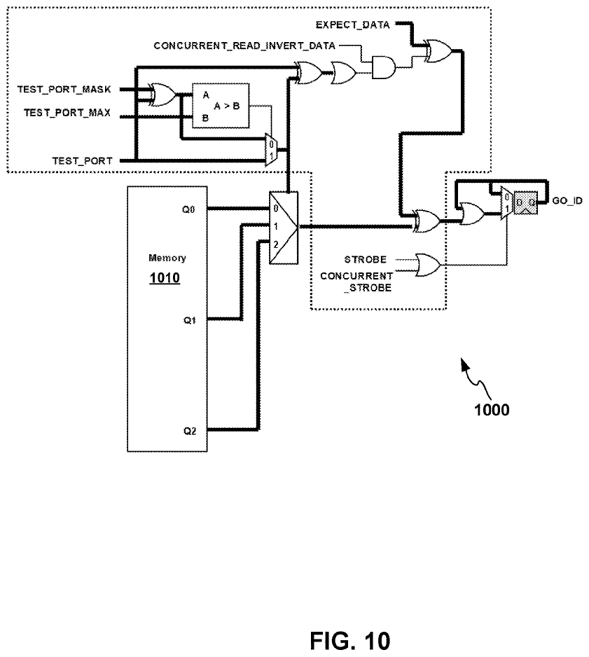

FIG. 10 illustrates an example block diagram of serial comparison circuitry 1000 for concurrent read data a that may be implemented according to various embodiments of the disclosed technology. A memory 1010 has three read output ports Q0, Q1 and Q2. The serial comparison circuitry 1000 is configured to perform a comparison of data outputted from the three read output ports Q0, Q1 and Q2 sequentially after performing a concurrent read command. The read operation is performed on all ports simultaneously. The data outputted from the three read output ports Q0, Q1 and Q2 are assumed to be latched.

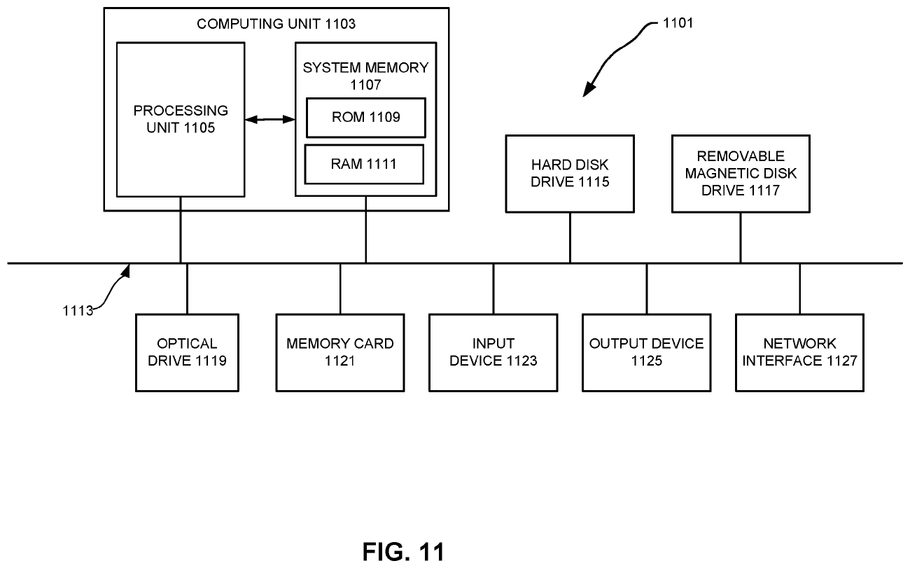

Various examples of the disclosed technology may be implemented through the execution of software instructions by a computing device, such as a programmable computer. Accordingly, FIG. 11 shows an illustrative example of a computing device 1101. As seen in this figure, the computing device 1101 includes a computing unit 1103 with a processing unit 1105 and a system memory 1107. The processing unit 1105 may be any type of programmable electronic device for executing software instructions, but it will conventionally be a microprocessor. The system memory 1107 may include both a read-only memory (ROM) 1109 and a random access memory (RAM) 1111. As will be appreciated by those of ordinary skill in the art, both the read-only memory (ROM) 1109 and the random access memory (RAM) 1111 may store software instructions for execution by the processing unit 1105.

The processing unit 1105 and the system memory 1107 are connected, either directly or indirectly, through a bus 1113 or alternate communication structure, to one or more peripheral devices. For example, the processing unit 1105 or the system memory 1107 may be directly or indirectly connected to one or more additional memory storage devices, such as a “hard” magnetic disk drive 1115, a removable magnetic disk drive 1117, an optical disk drive 1119, or a flash memory card 1121. The processing unit 1105 and the system memory 1107 also may be directly or indirectly connected to one or more input devices 1123 and one or more output devices 1125. The input devices 1123 may include, for example, a keyboard, a pointing device (such as a mouse, touchpad, stylus, trackball, or joystick), a scanner, a camera, and a microphone. The output devices 1125 may include, for example, a monitor display, a printer and speakers. With various examples of the computer 1101, one or more of the peripheral devices 1115-1125 may be internally housed with the computing unit 1103. Alternately, one or more of the peripheral devices 1115-1125 may be external to the housing for the computing unit 1103 and connected to the bus 1113 through, for example, a Universal Serial Bus (USB) connection.

With some implementations, the computing unit 1103 may be directly or indirectly connected to one or more network interfaces 1127 for communicating with other devices making up a network. The network interface 1127 translates data and control signals from the computing unit 1103 into network messages according to one or more communication protocols, such as the transmission control protocol (TCP) and the Internet protocol (IP). Also, the interface 1127 may employ any suitable connection agent (or combination of agents) for connecting to a network, including, for example, a wireless transceiver, a modem, or an Ethernet connection. Such network interfaces and protocols are well known in the art, and thus will not be discussed here in more detail.

It should be appreciated that the computer 1101 is illustrated as an example only, and it is not intended to be limiting. Various embodiments of the disclosed technology may be implemented using one or more computing devices that include the components of the computer 1101 illustrated in FIG. 11, which include only a subset of the components illustrated in FIG. 11, or which include an alternate combination of components, including components that are not shown in FIG. 11. For example, various embodiments of the disclosed technology may be implemented using a multi-processor computer, a plurality of single and/or multiprocessor computers arranged into a network, or some combination of both.

### CONCLUSION

Having illustrated and described the principles of the disclosed technology, it will be apparent to those skilled in the art that the disclosed embodiments can be modified in arrangement and detail without departing from such principles. In view of the many possible embodiments to which the principles of the disclosed technologies can be applied, it should be recognized that the illustrated embodiments are only preferred examples of the technologies and should not be taken as limiting the scope of the disclosed technology. Rather, the scope of the disclosed technology is defined by the following claims and their equivalents. We therefore claim as our disclosed technology all that comes within the scope and spirit of these claims.

What is claimed is:

1. A memory-testing circuit in a circuit configured to perform a test on one or more memories in the circuit, each of the one or more memories having a plurality of logical ports, the plurality of logical ports being divided into a plurality of test ports, each of the plurality of test ports being capable of both write and read operations and comprising one or two logical ports, the memory-testing circuit comprising:
a test algorithm control unit configured to implement a test algorithm, the test algorithm comprising a sequence of read and write operations, each execution of the test algorithm performing a memory test through one of the plurality of test ports, one logical port in the test port under test configured to receive an algorithm command corresponding to one read operation or one write operation in the sequence of read and write operations, logical ports that are not receiving the algorithm command configured to receive concurrent commands generated based on the test algorithm;
a reference address generator configured to generate, based on the test algorithm, a reference address for the one logical port in the test port under test;
one or more concurrent address generators configured to generate, based on the reference address, one or more concurrent addresses for the logical ports that receive the concurrent commands;
a test port counter configured to increment after each execution of the test algorithm and generate a test port count signal; and
address selecting circuitry for each of the one or more memories configured to select, based on an address selection signal, the reference address or one of the one or more concurrent addresses for each of the plurality of logical ports, the address selection signal being generated based on the test port count signal.

2. The memory-testing circuit recited in claim 1, further comprising:
a global control signal generator configured to generate, based on the test algorithm, the algorithm command and the concurrent commands; and
a local control signal generator in a memory test interface circuit for each of the one or more memories, the local control signal generator configured both to deliver the algorithm command to the one logical port in the test port under test and the concurrent commands to the logical ports that are not receiving the algorithm command and to generate, based on the test port count signal, the address selection signal.

3. The memory-testing circuit recited in claim 1, wherein the address selection signal comprises a row address selection signal and a column address selection signal and is configurable to allow a logical port to receive row address of the one of the one or more concurrent addresses and column address of the reference address, column address of the one of the one or more concurrent addresses and row address of the reference address, or both the row address and the column address of the one of the one or more concurrent addresses.

4. The memory-testing circuit recited in claim 1, wherein the one or more concurrent address generators comprises:
a global concurrent address generator configured to generate a global concurrent address based on the reference address; and
a local concurrent address generator in a memory test interface circuit for each of the one or more memories, the local concurrent address generator configured to receive the global concurrent address and to output the one or more concurrent addresses.

5. The memory-testing circuit recited in claim 4, wherein the one or more concurrent addresses are the same as the global concurrent address.

6. The memory-testing circuit recited in claim 4, wherein the local concurrent address generator is configured to generate the one or more concurrent addresses based on the global concurrent address, no more than one of the one or more concurrent addresses for write-capable logical ports being the same as the global concurrent address.

7. The memory-testing circuit recited in claim 4, wherein row address of the global concurrent address is derived from row address of the reference address by adding or subtracting 1, and column address of the global concurrent address is derived from column address of the reference column address by adding or subtracting 1.

8. The memory-testing circuit recited in claim 7, wherein the adding or subtracting 1 is based on whether the reference address changes in an ascending order or in a descending order.

9. The memory-testing circuit recited in claim 1, wherein each of the one or more concurrent addresses is obtained at least in part by applying a concurrent address mask to one or more bits of the reference address.

10. The memory-testing circuit recited in claim 9, wherein the concurrent address mask replaces selected bits of the reference address with a unique fixed bit pattern, inverts one or a unique combination of selected bits of the reference address, or both.

11. The memory-testing circuit recited in claim 1, wherein each of the one or more concurrent address generators is in a memory test interface circuit coupled to each of the one or more memories.

12. The memory-testing circuit recited in claim 11, wherein each of the one or more concurrent address generators comprises:
inverter circuitry configured to invert a least significant bit of an intermediate concurrent address, the intermediate concurrent address being the reference address or the reference address minus an offset; and
bit replacing circuitry to replace selected bits of the intermediate concurrent address with different fixed bit patterns for different logical ports.

13. The memory-testing circuit recited in claim 12, wherein the inverting and the replacing are performed on both row address and column address, and wherein the address selection signal comprises a row address selection signal and a column address selection signal and is configurable to allow a logical port to receive row address of the one of the one or more concurrent addresses and column address of the reference address, column address of the one of the one or more concurrent addresses and row address of the reference address, or both the row address and the column address of the one of the one or more concurrent addresses.

14. The memory-testing circuit recited in claim 13, wherein some or all of the one or more concurrent address generators comprise address threshold checking circuitry configured to output row address of the intermediate concurrent address, the row address of the intermediate concurrent address being the same as row address of the reference address if the row address of the reference address is smaller than a predetermined threshold value or an address obtained by subtracting an offset value from the row address of the reference address if the row address of the reference address is greater than or equal to the predetermined threshold value.

15. One or more computer-readable media storing computer-executable instructions for causing a computer to perform a method, the method comprising:
creating, in a circuit design, a memory-testing circuit configured to perform a test on one or more memories in the circuit design, each of the one or more memories having a plurality of logical ports, the plurality of logical ports being divided into a plurality of test ports, each of the plurality of test ports being capable of both write and read operations and comprising one or two logical ports, the memory-testing circuit comprising:
a test algorithm control unit configured to implement a test algorithm, the test algorithm comprising a sequence of read and write operations, each execution of the test algorithm performing a memory test through one of the plurality of test ports, one logical port in the test port under test configured to receive an algorithm command corresponding to one read operation or one write operation in the sequence of read and write operations, logical ports that are not receiving the algorithm command configured to receive concurrent commands generated based on the test algorithm;
a reference address generator configured to generate, based on the test algorithm, a reference address for the one logical port in the test port under test;
one or more concurrent address generators configured to generate, based on the reference address, one or more concurrent addresses for the logical ports that receive the concurrent commands;
a test port counter configured to increment after each execution of the test algorithm and generate a test port count signal; and
address selecting circuitry for each of the one or more memories configured to select, based on an address selection signal, the reference address or one of the one or more concurrent addresses for each of the plurality of logical ports, the address selection signal being generated based on the test port count signal.

16. The one or more computer-readable media recited in claim 15, wherein the memory-testing circuit further comprises:
a global control signal generator configured to generate, based on the test algorithm, the algorithm command and the concurrent commands; and
a local control signal generator in a memory test interface circuit for each of the one or more memories, the local control signal generator configured both to deliver the algorithm command to the one logical port in the test port under test and the concurrent commands to the logical ports that are not receiving the algorithm command and to generate, based on the test port count signal, the address selection signal.

17. The one or more computer-readable media recited in claim 15, wherein the address selection signal comprises a row address selection signal and a column address selection signal and is configurable to allow a logical port to receive row address of the one of the one or more concurrent addresses and column address of the reference address, column address of the one of the one or more concurrent addresses and row address of the reference address, or both the row address and the column address of the one of the one or more concurrent addresses.

18. The one or more computer-readable media recited in claim 15, wherein the one or more concurrent address generators comprises:
a global concurrent address generator configured to generate a global concurrent address based on the reference address; and
a local concurrent address generator in a memory test interface circuit for each of the one or more memories, the local concurrent address generator configured to receive the global concurrent address and to output the one or more concurrent addresses.

19. The one or more computer-readable media recited in claim 18, wherein the one or more concurrent addresses are the same as the global concurrent address.

20. The one or more computer-readable media recited in claim 18, wherein the local concurrent address generator is configured to generate the one or more concurrent addresses based on the global concurrent address, no more than one of the one or more concurrent addresses for write-capable logical ports being the same as the global concurrent address.

21. The one or more computer-readable media recited in claim 18, wherein row address of the global concurrent address is derived from row address of the reference address by adding or subtracting 1, and column address of the global concurrent address is derived from column address of the reference column address by adding or subtracting 1.

22. The one or more computer-readable media recited in claim 21, wherein the adding or subtracting 1 is based on whether the reference address changes in an ascending order or in a descending order.

23. The one or more computer-readable media recited in claim 15, wherein each of the one or more concurrent addresses is obtained at least in part by applying a concurrent address mask to one or more bits of the reference address.

24. The one or more computer-readable media recited in claim 23, wherein the concurrent address mask replaces selected bits of the reference address with a unique fixed bit pattern, inverts one or a unique combination of selected bits of the reference address, or both.

25. The one or more computer-readable media recited in claim 15, wherein each of the one or more concurrent address generators is in a memory test interface circuit coupled to each of the one or more memories.

26. The one or more computer-readable media recited in claim 25, wherein each of the one or more concurrent address generators comprises:
inverter circuitry configured to invert a least significant bit of an intermediate concurrent address, the intermediate concurrent address being the reference address or the reference address minus an offset; and
bit replacing circuitry to replace selected bits of the intermediate concurrent address with different fixed bit patterns for different logical ports.

27. The one or more computer-readable media recited in claim 26, wherein the inverting and the replacing are performed on both row address and column address, and wherein the address selection signal comprises a row address selection signal and a column address selection signal and is configurable to allow a logical port to receive row address of the one of the one or more concurrent addresses and column address of the reference address, column address of the one of the one or more concurrent addresses and row address of the reference address, or both the row address and the column address of the one of the one or more concurrent addresses.

28. The one or more computer-readable media recited in claim 27, wherein some or all of the one or more concurrent address generators comprise address threshold checking circuitry configured to output row address of the intermediate concurrent address, the row address of the intermediate concurrent address being the same as row address of the reference address if the row address of the reference address is smaller than a predetermined threshold value or an address obtained by subtracting an offset value from the row address of the reference address if the row address of the reference address is greater than or equal to the predetermined threshold value.
